(19) United States
(12) Patent Application Publication
(10) Pub. No.: US 2006/0199499 A1
(43) Pub. Date: Sep. 7, 2006

(54) Fastening structure

(76) Inventor: Cheng-Yu Tsai, Kuei San Hsiang (TW)

Correspondence Address: RABIN & Berdo, PC, 1101 14TH STREET, NW, SUITE 500, WASHINGTON, DC, 20005, US

(21) Appl. No.: 11/341,477

(22) Filed: Jan. 30, 2006

(30) Foreign Application Priority Data
Jan. 31, 2005 (TW) 094102950

(51) Int. Cl. H05K 5/00

(52) U.S. Cl. 454/184

(57) ABSTRACT

A fastening structure includes a fan, a fan seat, a base and a top cover of an electronic device. The fan is installed in the fan seat. A latch pin located on an inner bottom surface of the base of the electronic device is inserted into an anchor hole on an outer side of the bottom of the fan seat. The top cover may be coupled on the base of the electronic device to secure and anchor the fan seat. Hence the fan and fan seat may be installed and removed without using hand tools. The individual fans may be modularized and installed close to one another, and have their own wiring. Hence installation space may be saved.

### CROSS-REFERENCE TO RELATED APPLICATIONS

This non-provisional application claims priority under 35 U.S.C. § 119(a) on Patent Application No(s). 94102950 filed in Taiwan, R.O.C. on Jan. 31, 2005 the entire contents of which are hereby incorporated by reference.

### FIELD OF THE INVENTION

The invention relates to a fastening structure adopted for use on fans of electronic devices, and particularly to a fastening structure for fastening a fan in an electronic device without using hand tools.

### BACKGROUND OF THE INVENTION

As the demand for high speed data processing grows constantly, manufacturing and design of central processor units (CPU) have been innovated and developed continuously. Nowadays, the functions and processing speed of CPUs have improved dramatically, as operation voltage and frequency has also increased. As a result, heat generated by the CPU increases greatly. Overheating affects the CPU's normal operation. Hence a cooling apparatus is indispensable in the electronic device. Among the various types of cooling apparatus, the fan is most commonly used.

The fan is generally installed on the electronic device with screws. To install more fans in a limited space in order to increase cooling efficiency is a goal highly pursued in the industry. However, based on the present fan structure, packing more fans closely in a limited space is difficult. For instance, the wiring arrangement, assembly and disassembly of the fans are often troublesome. Thus saving space with the present fan fastening structure is difficult.

### SUMMARY OF THE INVENTION

In view of the aforesaid problems, the primary object of the invention is to provide a fastening structure to install a fan on an electronic device without using hand tools.

In order to achieve the foregoing object, the fastening structure according to the invention aims to install a fan on an electronic device. It includes a fan, a fan seat, a base and a top cover of an electronic device. The fan includes a body, a connection cable set and a connector. The connection cable set bridges the body and the connector. The fan seat has a housing body, a wiring portion, a holding trough and an anchor aperture. The fan is held by the housing body. The wiring portion and the holding trough are located on an outer side of the housing body for respectively holding the connection cable set and the connector. The anchor aperture is located on an outer edge of the bottom of the housing body. The base of the electronic device has a circuit connector and an anchor pin on an inner bottom surface. The circuit connector is connected to the connector in the holding trough. The anchor pin passes through the anchor hole. The top cover of the electronic device is coupled with the base to secure and anchor the fan seat.

By means of the invention, the fan and fan seat can be installed and removed without using hand tools. Moreover, individual fans may be modularized. The fans may be close to one another and have their own wiring. Hence installation space may be saved.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1A is an exploded view of a first embodiment of the invention;

FIG. 1B is an enlarged schematic view of the fan and fan seat of the first embodiment;

FIG. 1C is another schematic view of the fan seat of the first embodiment;

FIG. 2 is a perspective view of the first embodiment in an assembled condition;

FIGS. 3A, 3B and 3C are schematic views of the first embodiment in installation conditions;

FIG. 4A is an exploded view of a second embodiment of the invention;

FIG. 4B is an enlarged schematic view of the fan and fan seat of the second embodiment;

FIG. 5 is a perspective view of the second embodiment in an assembled condition; and

FIGS. 6A through 6D are schematic views of the second embodiment in installation conditions.

### DESCRIPTION OF THE PREFERRED EMBODIMENTS

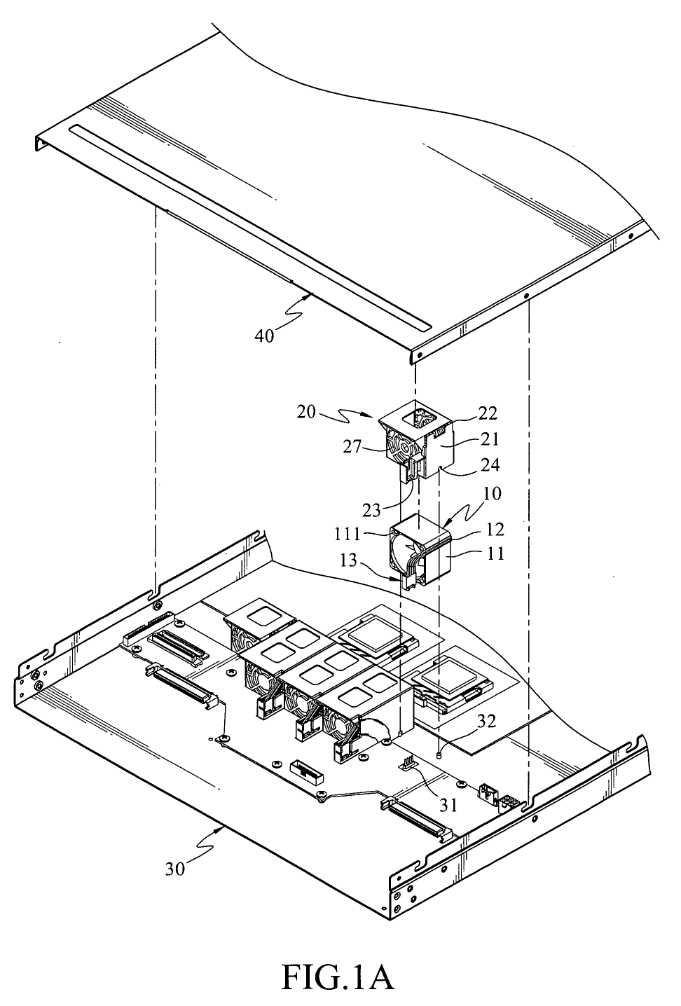

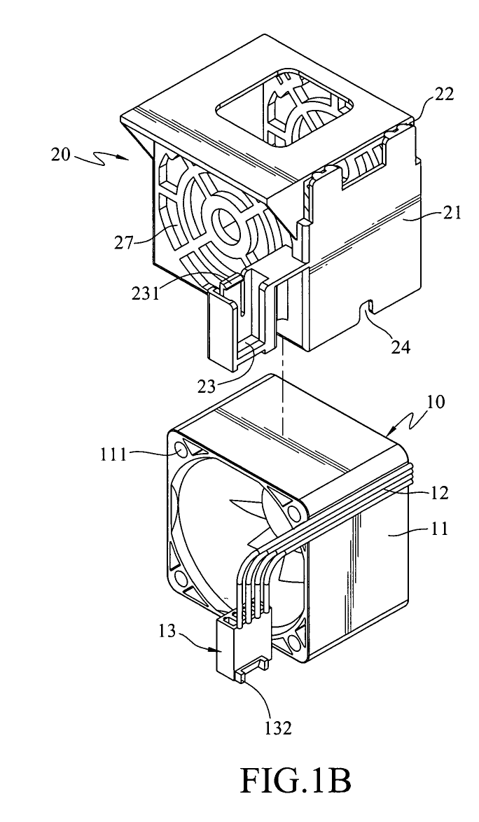

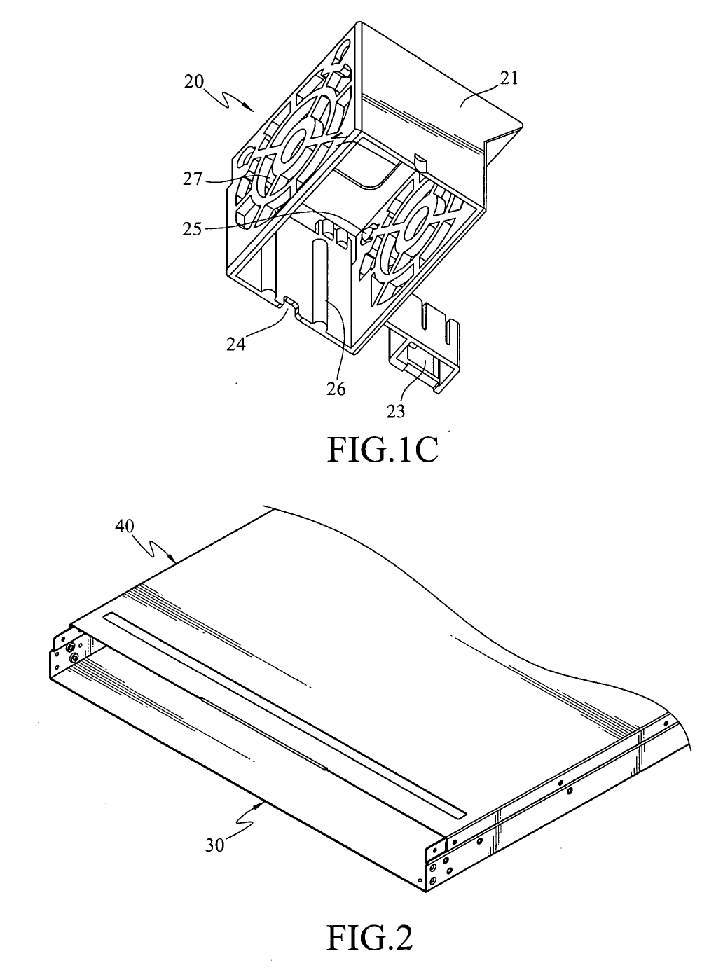

Refer to FIGS. 1A through 2 for the structure of a first embodiment of the invention. The fastening structure according to the invention aims to install a fan 10 on an electronic device. It includes the fan 10, a fan seat 20, a base 30 and a top cover 40 of the electronic device.

The fan 10 includes a body 11, a connection cable set 12 and a connector 13. The body 11 has an aperture 111. The connection cable set 12 bridges the body 11 and the connector 13. The connector 13 has an anchor member 132.

The fan seat 20 includes a housing body 21, a wiring portion 22, a holding trough 23, an anchor hole 24, a hook 25, a boss 26 and a radiation vent 27. The fan 10 is held by the housing body 21. The wiring portion 22 and the holding trough 23 are located on an outer side of the housing body 21 for respectively holding the connection cable set 12 and the connector 13. The wiring portion 22 has one end connected to the housing body 21 and another end removable from the housing body 21 with the one end being a pivot thereof. The another end is connected to the housing body 21 in normal conditions.

The holding trough 23 has an opening formed at a width corresponding to the width of the anchor member 132, and a latch hook 231 corresponding to the connector 13. The anchor hole 24 is located on an outer side of the bottom of the housing body 21 and is formed with a semi-circular cross section. The housing body 21 has a hook 25 corresponding to the aperture 111 and extending outwards from the housing body 21 to pass through the aperture 111 in order to secure the fan 10. The boss 26 is located in the housing body 21 to engage the connection cable set 12. The radiation vent 27 is formed on the housing body 21.

The base 30 of the electronic device includes a circuit connector 31 and an anchor pin 32 located on an inner bottom surface. The circuit connector 31 is connected to the connector 13 located in the holding trough 23. The anchor pin 32 passes through the anchor hole 24 and has one half latched by the anchor hole 24.

The top cover 40 of the electronic device is coupled with the base 30 to secure and anchor the fan seat 20.

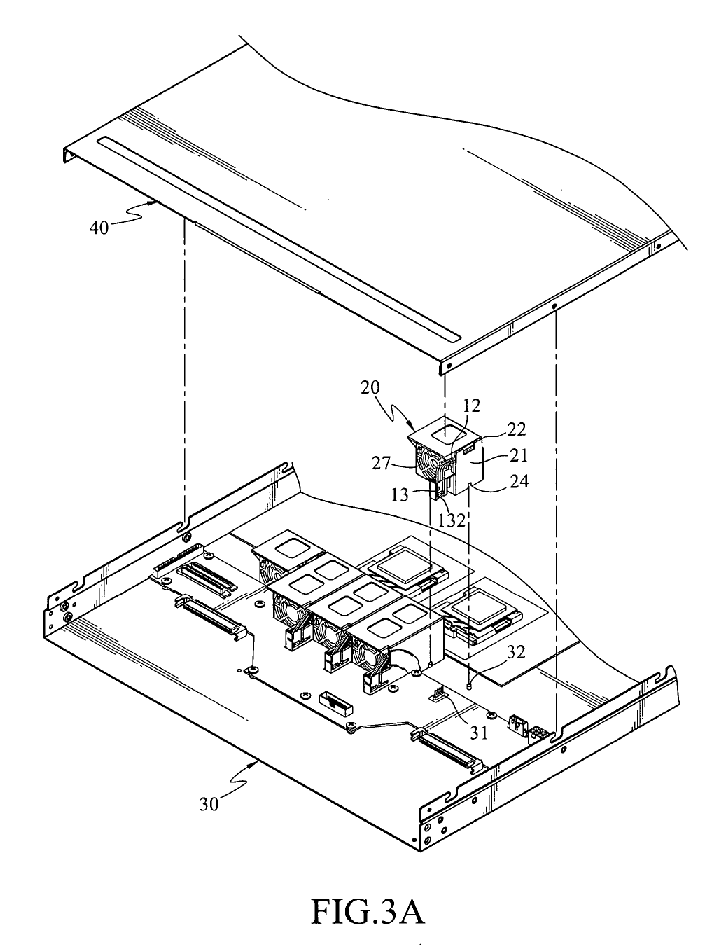

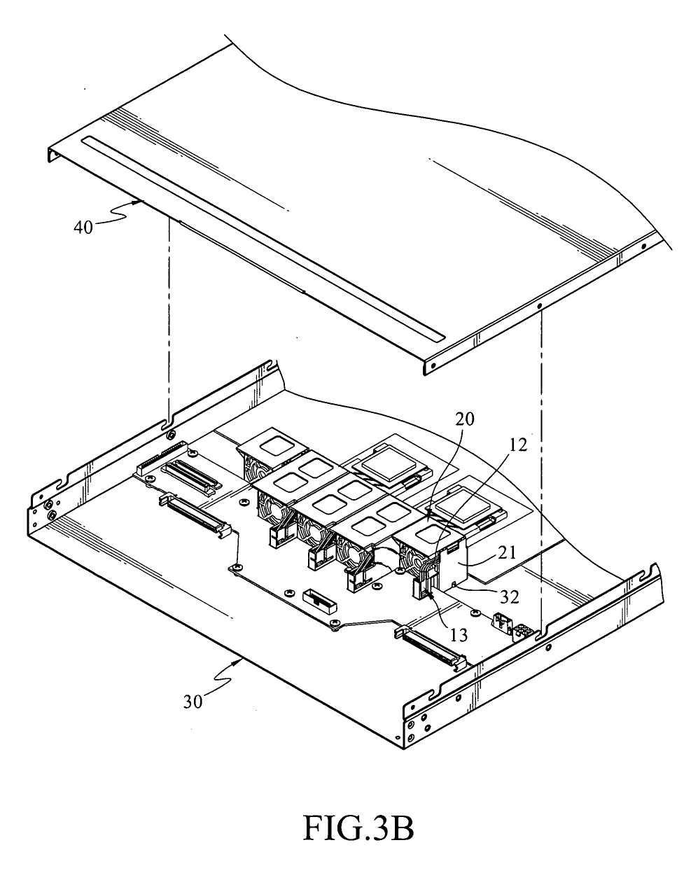

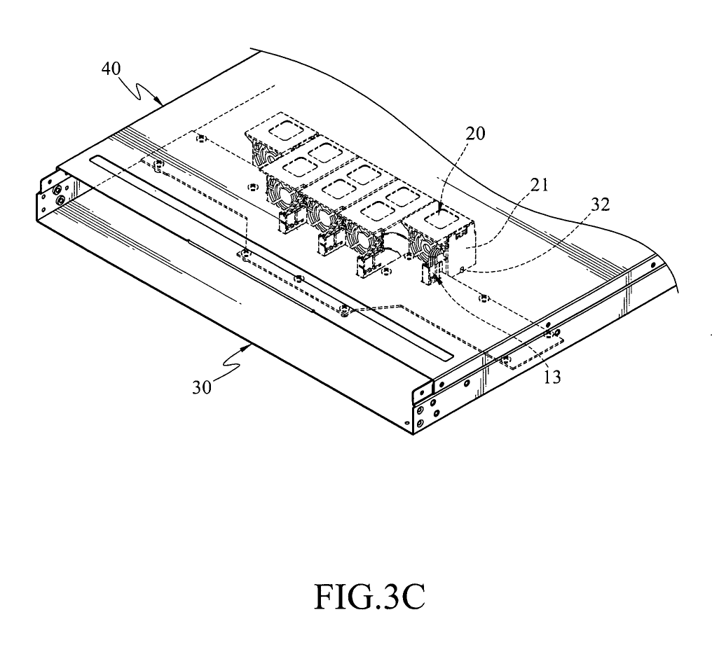

Refer to FIGS. 1A through 3C for more details and installation conditions of the first embodiment.

First, the hook 25 passes through the aperture 111 of the body 11 of the fan 10 to install the body 11 in the housing body 21 of the fan seat 20, and the connection cable set 12 is moved to pass one side of the boss 26 to form a cable layout; the wiring portion 22 is moved to another end of the housing body 21, and one end of the wiring portion 22 remote from the housing body 21 is moved; the connection cable set 12 is moved to pass through the wiring portion 22, and the other end of the wiring portion 22 is released to connect to the housing body 21; the connector 13 is placed in the hold trough 23; as the opening width of the holding trough 23 corresponds to the width of the anchor member 132, the anchor member 132 is confined by the holding trough 23, and the latch hook 231 is latched on one end of the connector 13 to keep the connector 13 from moving, hence the body 11 does not escape the fan seat 20; the cable connection set 12 is not separated from the wiring portion 22, and the connector 13 is held in the holding trough 23 without escaping. Hence the fan 10 can be installed on the fan seat 20.

The anchor pin 32 is then aligned with the anchor hole 24 to mount the fan seat 20 onto the base 30 of the electronic device. The circuit connector 31 is connected to the connector 13 held in the holding trough 23. As shown in the drawings, only one half of the anchor pin 32 is inserted in the anchor hole 24, hence one anchor pin 32 can hold two sets of the fan seat 20. Finally, the top cover 40 is coupled with the base 30 of the electronic device to hold and anchor the fan seat 20. When the fan 10 rotates, airflow is discharged through the radiation vent 27 to disperse heat. Thus by means of the invention, the fan 10 and fan seat 20 may be installed and removed without using hand tools. Moreover, the individual fans 10 may be modularized and installed close to each other. Each fan has its own wiring. Hence installation space may be saved.

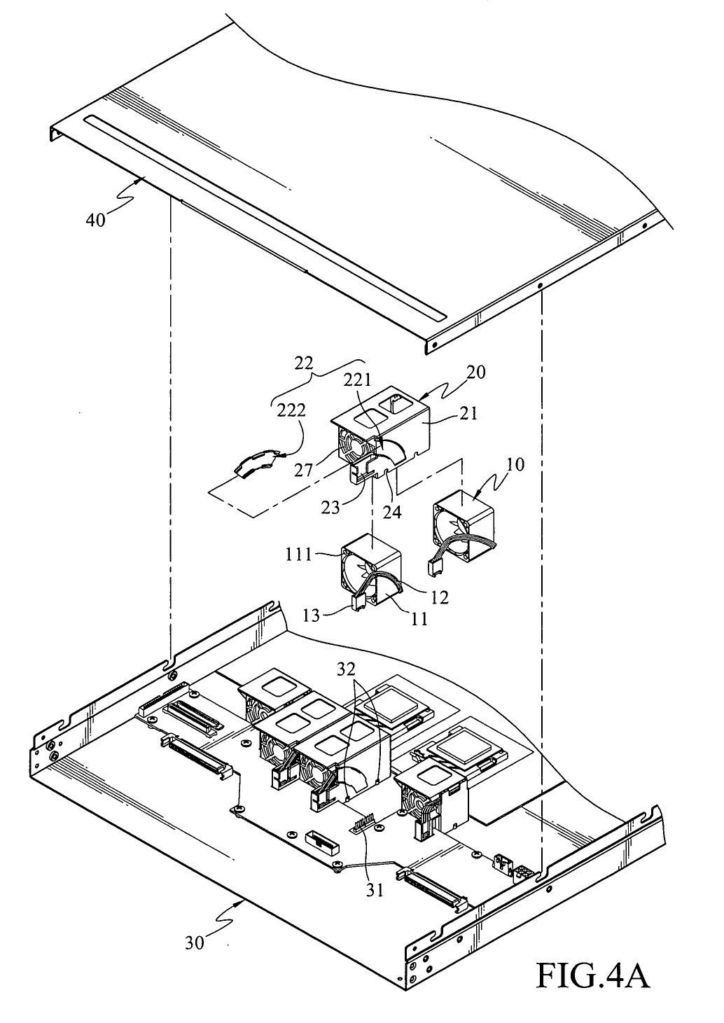

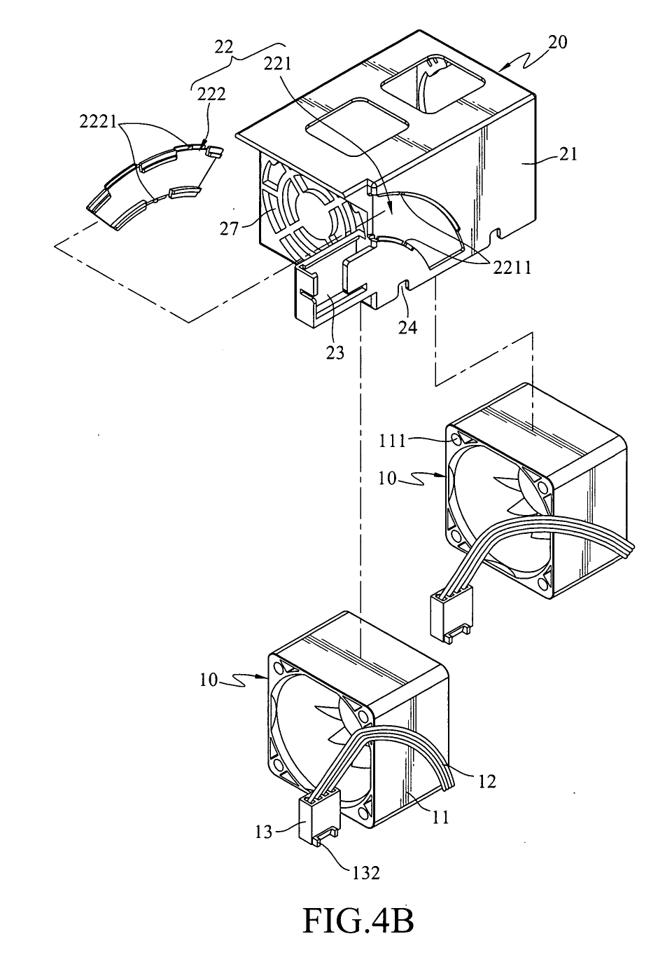

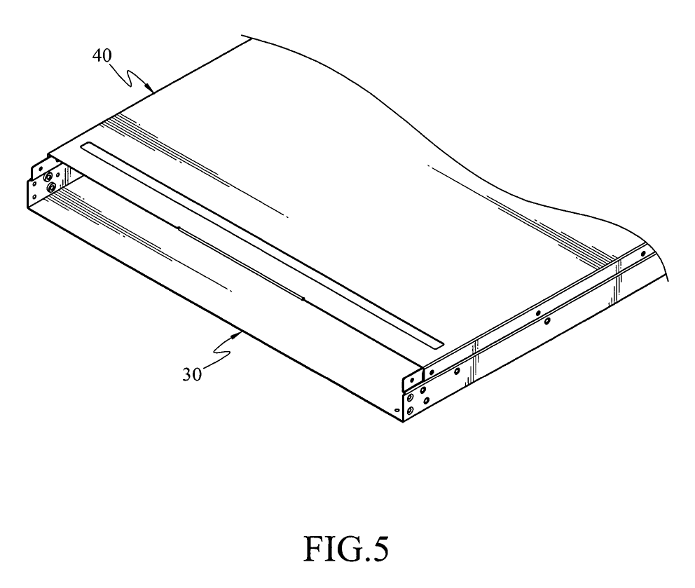

Refer to FIGS. 4A, 4B and 5 for the structure of a second embodiment of the invention.

The second embodiment differs from the first embodiment mainly in the wiring portion 22. The wiring portion 22 of the second embodiment includes a wiring trough 221, and a wiring cap 222 which is movably coupled with the wiring trough 221 and covers it. The wiring trough 221 includes a latch mortise 2211. The wiring cap 222 has a latch tenon 2221 corresponding to the latch mortise 2211 to anchor the wiring cap 222 on the wiring trough 221.

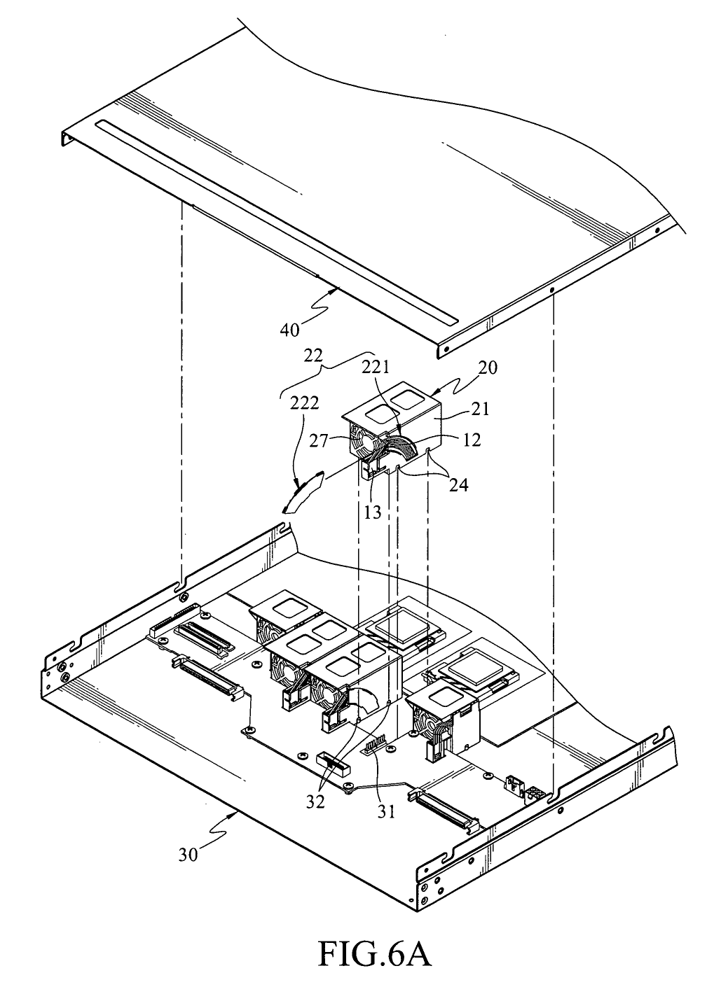

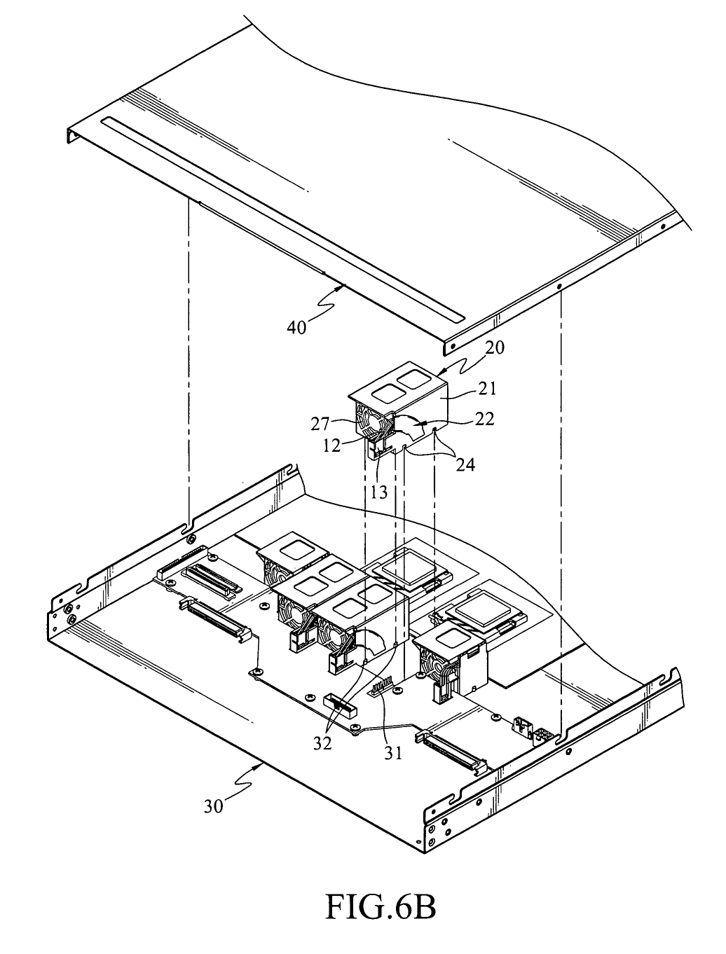

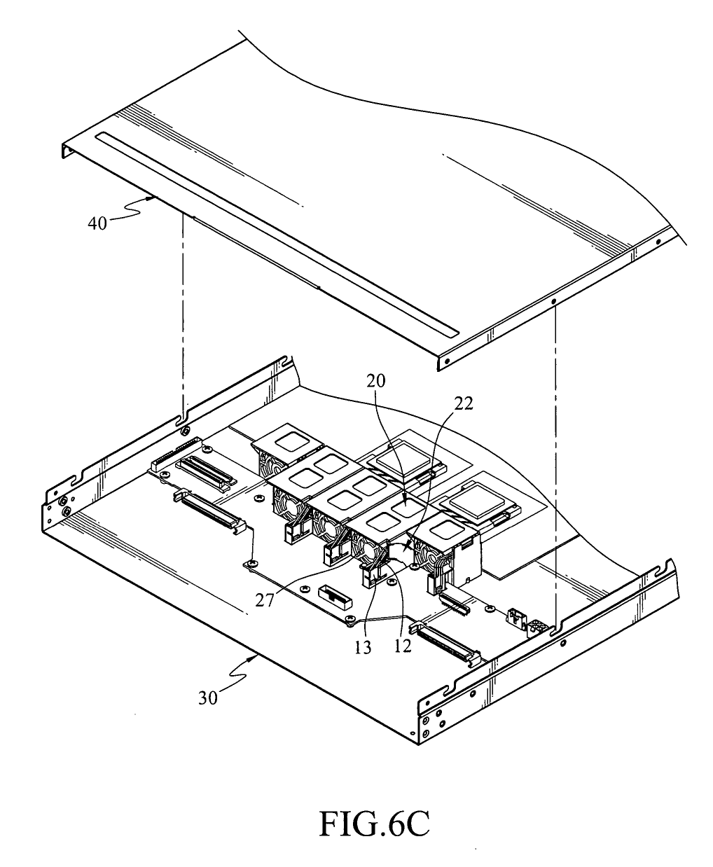

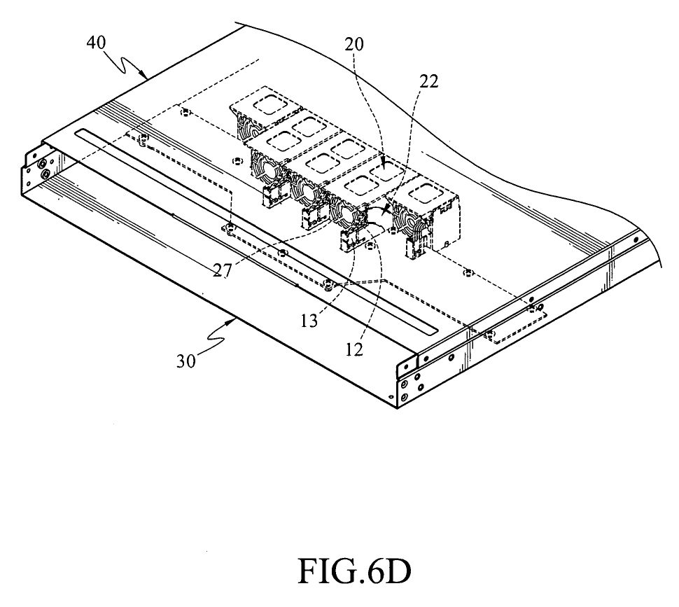

Refer to FIGS. 4A through 6D for more details and installation conditions of the second embodiment.

First, the hook 25 passes through the aperture 111 of the body 11 of the fan 10 to install the body 11 in the housing body 21 of the fan seat 20, and the connection cable set 12 is moved to pass one side of the boss 26 to form a cable layout; the connection cable set 12 is moved to pass through the wiring trough 221 of the wiring portion 22; the connector 13 is placed in the hold trough 23; as the opening width of the holding trough 23 corresponds to the width of the anchor member 132, the anchor member 132 is confined by the holding trough 23, and the latch hook 231 is latched on one end of the connector 13 to secure the connector 13 from moving. The wiring cap 222 is coupled with the wiring trough 221, and the latch tenon 2221 is coupled with the latch mortise 2222 to anchor the wiring cap 222 on the wiring trough 221 so that the body 11 does not escape from the fan seat 20. The connection cable set 12 also does not leave the wiring portion 22, and the connector 13 does not break away from the holding trough 23. Thus the fan 10 can be installed on the fan seat 20.

The anchor pin 32 is then aligned with the anchor hole 24 to mount the fan seat 20 onto the base 30 of the electronic device. The circuit connector 31 is connected to the connector 13 held in the holding trough 23. As shown in the drawings, only one half of the anchor pin 32 is inserted in the anchor hole 24, hence one anchor pin 32 can hold two sets of fan seat 20. Finally, the top cover 40 is coupled with the base 30 of the electronic device to secure and anchor the fan seat 20. When the fan 1Q rotates, airflow is discharged through the radiation vent 27 to disperse heat. Thus by means of the invention, the fan 10 and fan seat 20 may be installed and removed without using hand tools. Moreover, the individual fans 10 may be modularized and be installed close to each other. Each fan has its own wiring. Hence installation space may be saved.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A fastening structure, comprising:
a fan comprising a body, a connection cable set and a connector, wherein the connection cable set bridges the body and the connector;
a fan seat comprising a housing body, a wiring portion, a holding trough and an anchor hole, wherein the fan is held by housing body, the wiring portion and the holding trough are located on an outer side of the housing body for respectively holding the connection cable set and the connector, and the anchor hole is located on an outer side of the bottom of the housing body;
a base of an electronic device comprising a circuit connector and an anchor pin located on an inner bottom surface thereof, wherein the circuit connector is connected to the connector located in the holding trough, and the anchor pin passes through the anchor hole; and
a top cover of the electronic device coupling with the base to secure and anchor the fan seat.

2. The fastening structure of claim 1, wherein the fan further comprises an aperture.

3. The fastening structure of claim 2, wherein the housing body has a hook corresponding to the aperture and extending outwards from the housing body to pass through the aperture in order to secure the fan.

4. The fastening structure of claim 1, wherein the connector has an anchor member, and the holding trough has an opening formed at a width corresponding to the width of the anchor member.

5. The fastening structure of claim 1, wherein the housing body further has a boss located in the housing body to engage the connection cable set.

6. The fastening structure of claim 1, wherein the housing body further has a radiation vent.

7. The fastening structure of claim 1, wherein the wiring portion has one end connected to the housing body, and another end removable from the housing body with the one end being a pivot thereof.

8. The fastening structure of claim 1, wherein the wiring portion has one end connected to the housing body, and another end connected to the housing body.

9. The fastening structure of claim 1, wherein the wiring portion further includes a wiring trough and a wiring cap that correspond to each other, and the wiring cap is movably coupled on and covered the wiring trough.

10. The fastening structure of claim 7, wherein the wiring trough further has a latch mortise, and the wiring cap has a latch tenon corresponding to the latch mortise for anchoring the wiring cap on the wiring trough.

11. The fastening structure of claim 1, wherein the anchor hole has a semi-circular cross section.

12. The fastening structure of claim 1, wherein the holding trough further has a latch hook to latch one end of the connector so as to secure the connector from moving.
